(19) United States
(12) Patent Application Publication
(10) Pub. No.: US 2012/0176207 A1
(43) Pub. Date: Jul. 12, 2012

(54) PARTIALLY-FILLED ELECTRODE-TO-RESONATOR GAP

(75) Inventors: Clark Tu-Cuong Nguyen, Oakland, CA (US); Li-Wen Hung, Berkeley, CA (US)

(73) Assignee: THE REGENTS OF THE UNIVERSITY OF CALIFORNIA, Oakland, CA (US)

(21) Appl. No.: 12/826,454

(22) Filed: Jun. 29, 2010

Related U.S. Application Data
(63) Continuation of application No. PCT/US2009/030148, filed on Jan. 5, 2009.
(60) Provisional application No. 61/019,235, filed on Jan. 5, 2008.

(51) Int. Cl. H03H 9/00

(52) U.S. Cl. 333/186

(57) ABSTRACT

Method and apparatus for lowering capacitively-transduced resonator impedance within micromechanical resonator devices. Fabrication limits exist on how small the gap spacing can be made between a resonator and the associated input and output electrodes in response to etching processes. The present invention teaches a resonator device in which these gaps are then fully, or more preferably partially filled with a dielectric material to reduce the gap distance. A reduction of the gap distance substantially lowers the motional resistance of the micromechanical resonator device and thus the capacitively-transduced resonator impedance. Micromechanical resonator devices according to the invention can be utilized in a wide range of UHF devices, including integration within ultra-stable oscillators, RF filtering devices, radar systems, and communication systems.

### CROSS-REFERENCE TO RELATED APPLICATIONS

This application claims priority from, and is a 35 U.S.C. §111(a) continuation of, PCT international application number PCT/US2009/030148 filed on Jan. 5, 2009, incorporated herein by reference in its entirety, which claims priority from U.S. provisional application Ser. No. 61/019,235 filed on Jan. 5, 2008, incorporated herein by reference in its entirety.

This application is also related to PCT International Publication No. WO WO 2009/097167 published on Aug. 6, 2009, incorporated herein by reference in its entirety.

### STATEMENT REGARDING FEDERALLY SPONSORED RESEARCH OR DEVELOPMENT

This invention was made with Government support under Grant No. HR0011-06-1-0041 awarded by DARPA. The Government has certain rights in this invention.

### INCORPORATION-BY-REFERENCE OF MATERIAL SUBMITTED ON A COMPACT DISC

Not Applicable

### NOTICE OF MATERIAL SUBJECT TO COPYRIGHT PROTECTION

A portion of the material in this patent document is subject to copyright protection under the copyright laws of the United States and of other countries. The owner of the copyright rights has no objection to the facsimile reproduction by anyone of the patent document or the patent disclosure, as it appears in the United States Patent and Trademark Office publicly available file or records, but otherwise reserves all copyright rights whatsoever. The copyright owner does not hereby waive any of its rights to have this patent document maintained in secrecy, including without limitation its rights pursuant to 37 C.F.R. §1.14.

A portion of the material in this patent document is also subject to protection under the maskwork registration laws of the United States and of other countries. The owner of the maskwork rights has no objection to the facsimile reproduction by anyone of the patent document or the patent disclosure, as it appears in the United States Patent and Trademark Office publicly available file or records, but otherwise reserves all maskwork rights whatsoever. The maskwork owner does not hereby waive any of its rights to have this patent document maintained in secrecy, including without limitation its rights pursuant to 37 C.F.R. §1.14.

### BACKGROUND OF THE INVENTION

1. Field of the Invention

This invention pertains generally to resonator gap-filling methods, and more particularly to gap-filling within micromechanical resonator devices.

2. Description of Related Art

Capacitively driven vibrating micromechanical resonators are receiving ever-increasing interest for a wide range of applications. These devices have posted the highest Q′s of any on-chip resonator technology, with Q values exceeding 200,000 in the VHF range and exceeding 14,000 in the GHz range, wherein they are positioned as strong candidates for resonators that can satisfy requirements for the most stringent communications applications, such as military communications and radar applications. Among the applications these devices may address are channel-selective RF filtering, which can greatly enhance the robustness and security of communications; and ultra-stable oscillators, which further enhance secure communications while significantly improving the performance of radars. The most stringent of these applications often utilize cryogenically-cooled super-conducting circuits to achieve the needed Q's, where they suffer from enormous power consumption due to their need for cryogenic cooling. Since MEMS-based resonators can provide the needed Q's without the need for cryogenic cooling, and in orders of magnitude smaller size, they pose a very attractive opportunity in many applications, and are particular well-suited for use within portable communication devices.

However, although MEMS resonators have achieved impressive Q values, the capacitively transduced devices presently able to achieve such Q's have relatively weak electromechanical coupling coefficients. One significant shortcoming of present devices is that their electrode-to-resonator gaps cannot be made sufficiently small to optimize device operation. In response to gap size these devices typically offer higher-than-conventional impedances, e.g., orders of magnitude higher than 50Ω.

Accordingly a need exists for a system and method for reducing the gap sizes within capacitively transduced devices while retaining very high Q levels and low impedance. These needs and others are met within the present invention, which overcomes the deficiencies of previously developed resonator apparatus and methods.

### BRIEF SUMMARY OF THE INVENTION

The invention is a method for reducing electrode-to-resonator gaps toward orders of magnitude smaller gap spacing than previously available in response to filling the gap with a (usually dielectric) material that can be deposited conformally (e.g., via atomic layer deposition (ALD)), or other processes. This reduction in gap spacing allows orders of magnitude larger electromechanical coupling factors for vibrating micromechanical resonators, which in turn enables enormous decreases in their series motional resistance. Not only does motional resistance decrease; it does so by a factor of n⁴ times which is n³ times faster than the increase in electrode-to-resonator overlap capacitance. This decrease in motional resistance greatly raises the 1/(RₓCₙ) figure of merit that governs the frequency range of vibrating micromechanical circuits.

Application of the present invention allows for the fabrication of inexpensive capacitively-transduced micromechanical resonators which can more readily achieve the needed low impedances for conventional RF filters while maintaining quality factors (Q's) larger than achievable by resonators used today. This technology thus enables micro-scale resonators with simultaneous high Q and low motional resistance; i.e., with exceptional Q/Rₓ figure of merit. Three main recognitions are instrumental to enabling this invention: (1) lithographic or sacrificial layer etch methods for defining tiny (e.g., nm-scale) gaps are limited by resolution and diffusion limitations, respectively; (2) gap filling is a much more effective method for achieving smaller gaps; and (3) an electrode-to-resonator gap need not be filled by a conductive material to effect a smaller effective gap; rather, a dielectric can be used with virtually equivalent results, depending on the magnitude of the dielectric constant. The disclosed technology not only makes possible a higher capacitive transducer figure of merit for vibrating micromechanical resonators, but also prevents electrode-to-resonator shorting, thereby greatly enhancing the robustness of capacitively transduced devices.

The invention is amenable to being embodied in a number of ways, including but not limited to the following descriptions.

One embodiment of the invention is a micromechanical resonator device having a capacitive-transducer, comprising: (a) at least one input electrode; (b) at least one output electrode; (c) at least one resonator element retained proximal said input and output electrodes and adapted to provide sufficient unimpeded mechanical displacement for resonance; wherein a gap of distance d₁ exists between said resonator element and the input electrodes and/or output electrodes; and (d) an additional material (e.g., dielectric material) disposed on the resonator element, the electrodes, or a combination of the resonator element and the electrodes, to partially fill the gap distance between the resonator element and the electrodes to obtain a second gap distance d₂ which is smaller than first gap distance d₁. The reduction of the gap by partial filling with the additional material lowers the motional resistance of the micromechanical resonator device leading to a lowering of the capacitively-transduced resonator impedance.

One embodiment of the invention is a method of raising the efficacy of a capacitive-transducer within a micromechanical resonator device, comprising: fabricating a movable structure having proximal input and output electrodes; said structure configured with a gap between said structure and said electrodes that comprises a first gap distance d₁; at least partially-filling said gap with a dielectric material, wherein said first gap distance d₁ is reduced to a second gap distance d₂; and wherein reduction of said gap from said first gap distance to said second, smaller, gap distance raises the efficacy of the capacitive-transducer in its ability to move the structure once inputs are applied.

One embodiment of the invention is a method of lowering capacitively-transduced resonator impedance within a micromechanical resonator device, comprising: (a) fabricating a disk resonator having input and output electrodes about a disk resonator retained on a central stem attached to a substrate; (b) the disk resonator is retained on the stem above the substrate and with a gap (e.g., vacuum or air gap), having a first gap distance, d₁, between the disk resonator and the electrodes; (c) at least partially-filling the gap with a dielectric material, wherein the first gap distance d₁ is reduced to a second gap distance d₂. The reduction of the gap from the first gap distance d₁ to the second, smaller, gap distance d₂ lowers the motional resistance of the micromechanical resonator device and thus the capacitively-transduced resonator impedance.

One embodiment of the invention is a micromechanical resonator device, comprising: (a) a substrate; (b) at least one input electrode attached to the substrate; (c) at least one output electrode attached to the substrate; (d) a disk resonator retained proximal the input and output electrodes and retained above the substrate; (e) a central stem coupling the disk resonator to the substrate; and (f) a dielectric material disposed on the resonator and/or the electrodes to reduce the gap distance between the resonator and the electrodes. The reduction of gap distance by introducing the dielectric lowers the motional resistance of the micromechanical resonator device and thus the capacitively-transduced resonator impedance.

The present invention provides a number of beneficial aspects which can be implemented either separately or in any desired combination without departing from the present teachings.

An aspect of the invention is to provide a micromechanical resonator having high Q values and lowered impedance.

Another aspect of the invention is to utilize atomic layer deposition (ALD) process for partially filling the gap.

Another aspect of the invention is to utilize one or more oxide growth processes for partially filling the gap.

Another aspect of the invention is the ability to lower the impedance of the device from on the order of 500 kΩ down to 50Ω or less.

A still further aspect of the invention is to improve the characteristics of micromechanical resonators for use within a wide range of UHF equipment.

Further aspects of the invention will be brought out in the following portions of the specification, wherein the detailed description is for the purpose of fully disclosing preferred embodiments of the invention without placing limitations thereon.

### BRIEF DESCRIPTION OF THE SEVERAL VIEWS OF THE DRAWING(S)

The invention will be more fully understood by reference to the following drawings which are for illustrative purposes only:

FIG. 1 is an SEM image of a vibrating micromechanical disk resonator fabricated according to an embodiment of the present invention.

FIG. 2 is a graph of frequency characteristics for the 1.51 GHz disk resonator shown in FIG. 1, with a measured Q=11,555 in vacuum, and with a Q=10,100 in air.

FIG. 3A is a schematic of a capacitively transduced micromechanical disk resonator according to the present invention and shown with a typical bias, excitation and sense configuration.

FIG. 3B is a schematic of gap configurations for the disk resonator of FIG. 3A, showing a gap of d₁ and a reduced gap of d₂, according to aspects of the present invention.

FIG. 4A is a perspective view of a disk resonator.

FIG. 4B is a cross-sections of a laterally-driven wine-glass disk resonator, showing the elements prior to releasing of the disk structure.

FIG. 5A is a perspective view of a disk resonator.

FIG. 5B is a cross-section of a laterally-driven wine-glass disk resonator, showing the elements after final release of the disk structure.

FIGS. 6A-6B are schematics (pictorial and symbolic) for a partially-filled electrode-to-resonator gap according to aspects of the present invention.

FIG. 7 is an image of a micromechanical resonator having two-inputs and two outputs according to an aspect of the present invention.

FIG. 8 is a graph of frequency response for an implementation of the resonator of FIG. 7, showing a Q of 48,862 at 61 MHz.

FIG. 9 is an image of a sealed gap for a resonator after an atomic layer deposition (ALD) process according to an aspect of the present invention.

FIGS. 10A-10B are electrical field distribution diagrams within the gap for fully-filled and partially-filled gaps according to aspects of the present invention.

FIG. 11 is a cross-section view of an alternative gap filling process according to an aspect of the present invention.

FIG. 12 is a cross-section view of an another alternative gap filling process according to an aspect of the present invention.

### DETAILED DESCRIPTION OF THE INVENTION

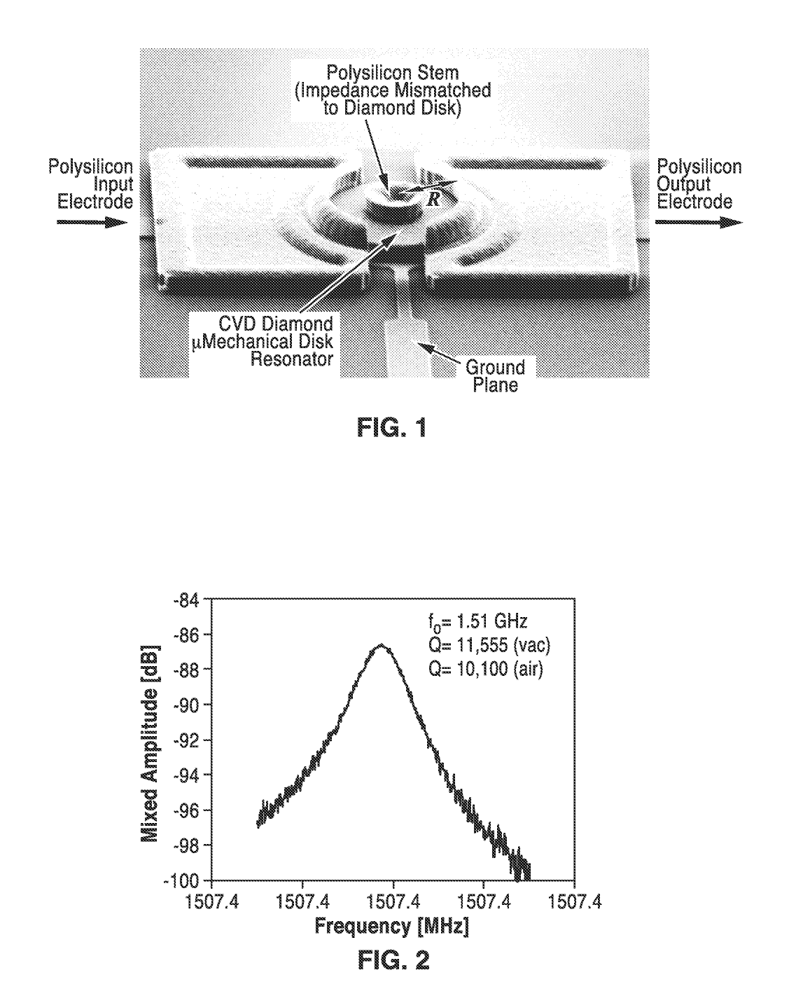

Referring more specifically to the drawings, for illustrative purposes the present invention is embodied in the apparatus generally shown in FIG. 1 through FIG. 12. It will be appreciated that the apparatus may vary as to configuration and as to details of the parts, and that the method may vary as to the specific steps and sequence, without departing from the basic concepts as disclosed herein.

1. Objectives.

The present invention is directed at providing electrode-to-resonator gap-filling methods that enable micromechanical resonator devices with simultaneous high Q (with Q>10,000) and low impedance (with motional resistance<100Ω) at GHz frequencies. The gap-filling strategies being pursued come in two types: (1) complete filling of the lateral gap spacing between the electrode and resonator surfaces to achieve a “solid-gap” micromechanical resonator, but with a dielectric constant substantially higher than previously used; and (2) partial filling of the electrode-to-resonator gap to attain a much smaller effective gap, but leaving enough space between electrode and resonator to allow unimpeded displacement. It should be appreciated that allowing unimpeded displacement results in achieving far higher values of Q. The former has been demonstrated using a silicon nitride dielectric to reduce the motional resistance of 60-MHz wine-glass mode disk resonators, while incurring only a small degradation in Q caused by the need to compress the silicon nitride film. The latter removes the need for gap-film compression, so has potential for greatly decreasing the motional resistance without incurring any Q reduction. Both methods are particularly well suited for implementation using atomic layer deposition in order to conformally and precisely deposit material, such as higher-k dielectric films, monolayer-by-monolayer into the already less than 100 nm electrode-to-resonator gaps of fabricated disk resonator devices. It should also be appreciated, however, that other techniques can be utilized for reducing, or filling, gaps according to the present invention.

2. Technical Foundation.

The present invention is directed at MEMS-based vibrating micromechanical resonator technology that yield tiny on-chip resonators (e.g., disks, rings and other structures), vibrating at frequencies over 1 GHz with Q's >10,000. These devices have generated substantial interest for use in frequency control and timekeeper applications, and in particular for communications.

FIG. 1 illustrates an example embodiment of a scanning electron micrograph (SEM) of a radial-contour mode disk resonator of the present invention. Although disk resonators are exemplified within the embodiments of the present invention, it should be appreciated that the invention is application to any capacitive-transducer within a micromechanical resonator device. One example embodiment of the device is configured with a 20 μm diameter (10 μm radius), 3 μm thick polydiamond disk suspended by a polysilicon stem self-aligned to be exactly at its center. This embodiment of the device is enclosed by doped polysilicon electrodes spaced less than 80 nm from the disk perimeter. It should be appreciated that the dimensions are provided to demonstrate a specific device operating with specific frequency and parameters. The size and shape of components is determined by the application as will be recognized by one of ordinary skill in the art.

FIG. 2 is a graph of resonance for the resonator of FIG. 1, showing amplitude in dB with respect to frequency. From these results it is seen that the resonator demonstrates an impressive room-temperature on-chip Q=11,555 in vacuum, and with a Q=10,100 in air.

When vibrating in its radial contour mode, the disk expands and contracts around its perimeter, in a motion reminiscent of breathing, and in what effectively amounts to a high-stiffness, high-energy, extensional mode. Since the center of the disk corresponds to a node location for the radial contour vibration mode shape, anchor losses through the supporting stem are greatly suppressed, allowing this design to retain a very high Q even at this UHF frequency.

Unfortunately, the exceptional Q's of these resonators are not easy to access, because the impedances of these tiny devices are often much larger than that of the system into which they are being utilized. For example, many of today's systems are designed around 50Ω impedances. The use of 50Ω is a convention that derives mainly from the need to route signals through relatively high capacitance environments, such as those of the printed circuit boards (pc boards) which are typically utilized for electronic system integration. Indeed, as more components are integrated onto a single silicon chip, e.g., using the technology of the present invention, system impedances need no longer adhere to a 50Ω convention, since off-chip board-level capacitors need no longer be driven. In response to these levels of integration system impedances will likely rise to take advantage of certain noise benefits. For example, the use of a high system impedance helps to desensitize a system from losses arising from parasitic resistance (e.g., wire resistance). It further allows more optimal noise matching to transistor-based functions, for which noise figure can be minimized when driven by optimal source resistances, which are often higher than 50Ω. However, even when completely integrated on-chip, system impedances will likely still not rise past the kΩ range, since finite chip-level capacitance will still place a limit on the magnitude of impedance. Thus, design methodologies that allow reduction and tailoring of capacitive-transducer impedances down to the kΩ range, or less, at GHz frequencies are still desirable. In addition, to maintain compatibility with off-chip circuits (whether they become legacy or not), impedances down to 50Ω are also still desired in many applications. It should be noted that the present invention has demonstrated the ability to reach impedance values down to or below approximately 5Ω.

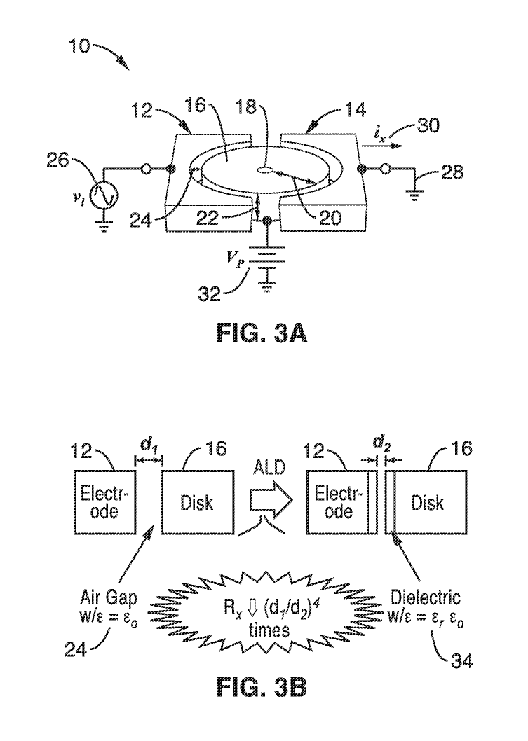

FIG. 3A illustrates an example embodiment 10 of a capacitively transduced micromechanical disk resonator configured with a typical bias arrangement, excitation, and sensing configuration. An input electrode 12 and output electrode 14 are shown on either side of a disk 16 having a supporting stem 18. The disk is shown with radius 20, height 22, and gap between disk and electrodes 24. A signal vᵢ 26 and ground 28 are shown coupled to input and output electrodes, respectively, wherein a current iₓ 30 flows. A DC bias voltage Vₚ 32 is shown applied to disk 16. It should be appreciated that the signals may be configured in alternative configurations and ways without departing from the teachings of the present invention.

FIG. 3B depicts the results of gap filling between disk and electrodes. On the left side of the figure a portion of a disk and electrode having a gap 24 d₁, are shown such as in response to conventional processing. On the right side of the figure the electrode is shown having a gap d₂, in response to gap-filling methods according to the present invention. It will be noted that gap 24 has thus been reduced in response to the introduction of dielectric 34 to reduce gap width to d₂.

One method for lowering capacitively-transduced resonator impedances is the partial filling of resonator-to-electrode capacitive gap in order to effectively reduce the gap spacing. The basic concept is illustrated in FIG. 3B, which magnifies the electrode-to-resonator gap of a capacitively-transduced micromechanical disk resonator, explicitly depicting two cases: an unfilled gap and a partially filled gap. For both cases, the motional resistance Rₓ across the resonator is given by:

$${R}_{x} = \frac{{ω}_{0} {m}_{r}}{{{QV}_{P}^{2} ( \partial C / \partial x )}^{2}} \approx \frac{{ω}_{0} {m}_{r} {d}_{0}^{4}}{{{QV}_{P}^{2} ( {ɛ}_{0} {A}_{0} )}^{2}} \qquad ( 1 )$$

where Ω₀ is the radian resonance frequency of the disk, mᵣ is its equivalent dynamic mass, Q is its quality factor, Vₚ is the dc-bias voltage applied to the resonant structure, ∂C/∂x is the change in electrode-to-resonator overlap capacitance per unit displacement, ε₀ is the permittivity in vacuum, A₀ is the electrode-to-resonator overlap area; and d₀ is the electrode-to-resonator gap spacing. Clearly, the gap spacing strongly influences the Rₓ, which has a fourth power dependence on this spacing. This in turn means that a reduction in gap spacing from the d₁ of the unfilled gap to d₂ of the partially-filled gap will lower the motional resistance of the device by (d₁/d₂)⁴, which can be extremely large. In particular, if the gap spacing is scaled by 10 times, the motional resistance Rₓ would drop by four orders of magnitude. In other words, 500 kΩ of motional resistance would become 50Ω, while the present invention allows reaching impedance down to 5Ω or even below. Alternatively, motional resistance could also be significantly reduced by smaller (d₁/d₂) ratio combined with other improvements to the mechanically-coupled resonator array designs.

Whichever approach is adopted, it is clear that if the gap can be scaled to smaller values than the 80 nm achieved so far by the lateral gap process used to fabricate the disk resonator of FIG. 1, then the motional resistance of the disk might be scaled by several orders of magnitude.

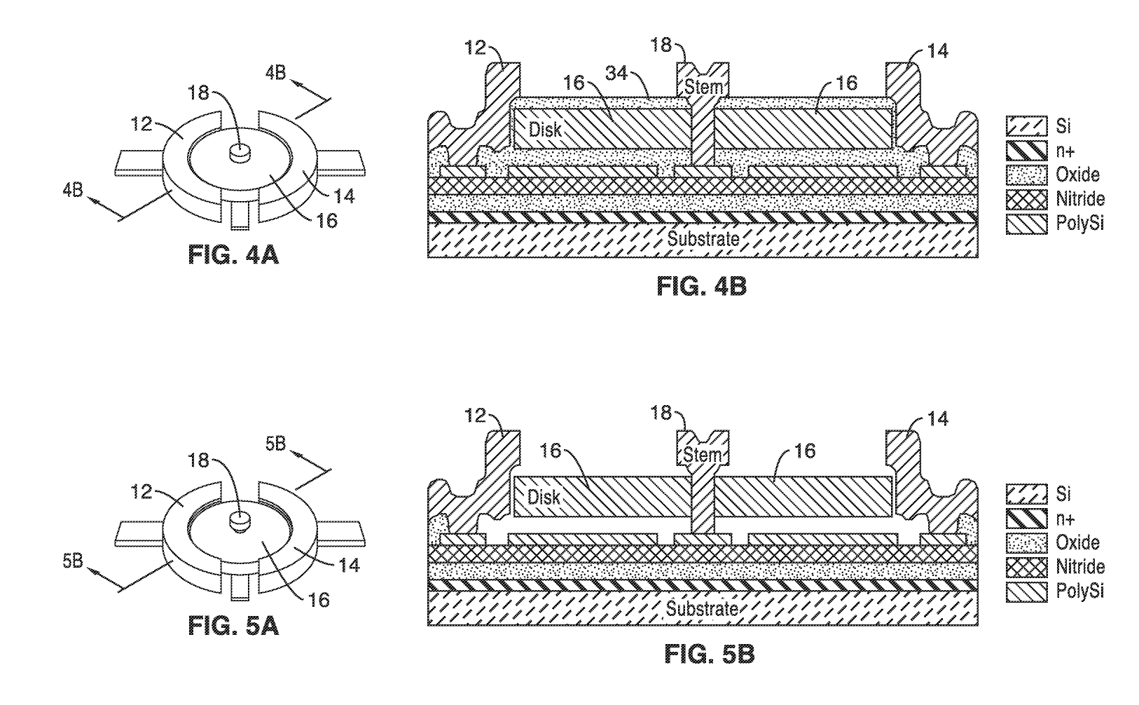

Yet problems arise in achieving a tiny gap using conventional methods, in particular, the lateral gap process achieves its sub-100 nm lateral gaps using a sacrificial oxide sidewall film that is sandwiched between the resonator and electrode during intermediate process steps, but is then removed via a liquid hydrofluoric acid release etchant at the end of the process to achieve the tiny gap. The last few steps of the process are then depicted in FIG. 4A-5B.

FIG. 4A and FIG. 5A illustrate a laterally driven wine-glass disk resonator whose cross-sections are shown respectively in FIG. 4B and FIG. 5B. The same structures can be seen in these figures as are shown in FIG. 3A, in particular an input electrode 12, output electrode 14, disk 16, and supporting stem 18.

FIG. 4B and FIG. 5B depict late stage final release processing of a disk resonator structure, such as prior to gap filling according to the present invention. It should be appreciated that the electrode-to-resonator lateral gap spacing (prior to filling according to the present invention) is determined by the thickness of a sidewall sacrificial spacer layer that is removed during the release etch step. In FIG. 5B all the material surrounding the disk has now been removed during processing.

According to this process, sacrificial layers, including sidewall layers, are removed through wet etching to release structures that will eventually move. This approach to achieving lateral gaps, while effective for gap spacings above 50 nm, proves difficult for smaller gap spacings. In particular, smaller gap spacings make it more difficult for etchants to diffuse into the gap and get to the etch front; and simultaneously for etch by-products to diffuse away from the etch front. Utilization of a process that fills the gap using gaseous reactants, which can more easily access and escape from the gap, provides more effective fabrication when achieving tiny gaps, such as those which are smaller than that which can be achieved by a wet-etch-based sacrificial sidewall spacer process.

One very effective approach to filling small high-aspect-ratio gaps is to utilize atomic layer deposition (ALD), where a two-phase, two-precursor reaction is used to deposit highly conformal films one monolayer at a time. It is possible to deposit metals via ALD, reducing the electrode-to-resonator gap by filling with metal, although this requires a method of preventing the shorting of input and output leads and structures. Accordingly, the embodiment discussed relies on the deposition of a high-k dielectric, where the permittivity of the dielectric should be high enough to allow the air (or vacuum) gap of FIG. 3C to set the overall capacitance value.

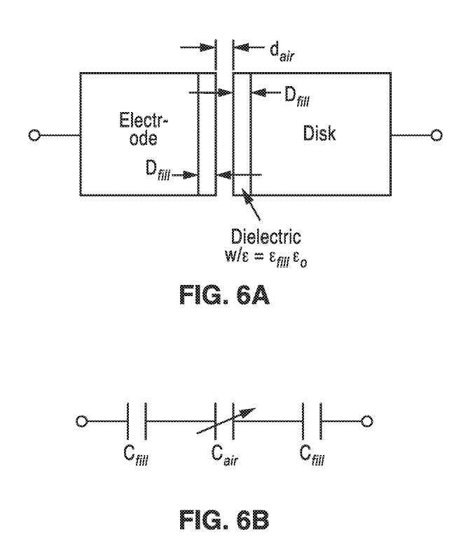

FIG. 6A-6B depict a cross-section of a partially-filled electrode-to-resonator gap in (FIG. 6A), along with its equivalent circuit (FIG. 6B). It will be appreciated that the capacitance between the electrode and resonator of FIG. 6A can be modeled by the series connection as shown in FIG. 6B. In this case, the total electrode-to-resonator capacitance is given by:

$$C ( x ) = {C}_{fill} ‖ {C}_{air} ( x ) ‖ {C}_{fill} = \frac{{C}_{fill}}{2} \vert \vert {C}_{air} ( x ) \qquad ( 2 )$$

from which (∂C/∂x) can be written (for small x) as:

$$\frac{\partial C}{\partial x} = {\frac{1}{{ɛ}_{0} {A}_{0}} [ \frac{{C}_{fill}}{2} \vert \vert {C}_{air} ]}^{2} = {\frac{1}{{d}_{air} {C}_{air}} [ \frac{{C}_{fill}}{2} \vert \vert {C}_{air} ]}^{2} \qquad ( 3 )$$

where Cₐᵢᵣ is the capacitance across the gap (e.g., air-gap or vacuum gap) for x=0; Cₐᵢᵣ(x) is this capacitance as a function of displacement x; C_{fill} is the capacitance across each dielectric-filled region; ε_{fill} is the permittivity of the dielectric filling material; and any dimensions shown are defined in FIG. 6A. Obviously, if C_{fill}>>Cₐᵢᵣ, then the capacitance and (∂C/∂x) reduce to:

$$C ( x ) = {C}_{air} ( x ) \to \frac{\partial C}{\partial x} = \frac{{C}_{air}}{{d}_{air}} \qquad ( 4 )$$

which are the values that would ensue if there were no dielectric and the electrode-to-resonator gap were equal to dₐᵢᵣ. In practice, C_{fill}/2 is preferably at least 10 times larger than Cₐᵢᵣ in order for Eq. (4) to hold, which means that the dielectric constant of the filling material should be at least the following:

$${ɛ}_{fill} \geq 20 {ɛ}_{0} \frac{{d}_{fill}}{{d}_{air}} \to C ( x ) \approx {C}_{air} ( x ) \qquad ( 5 )$$

where the gap dimensions d_{fill} and dₐᵢᵣ are shown in FIG. 6A. For the case where the gap spacing of a disk resonator is reduced from 100 nm to 20 nm using ALD, achieving a (d_{fill}/dₐᵢᵣ) ratio of (40/20) and provides a 625 times decrease in Rₓ, Eq. (5) suggests that the relative permittivity of the dielectric filling material should be >40 to allow the use of Eq. (4) to determine (∂C/∂x); otherwise Eq. (3) should be used. For example with a relative permittivity >40, a TiO₂ would be a good choice of dielectric. Fortunately, processes for depositing TiO₂ using ALD already exist, although to maximize dielectric constant these processes should be optimized.

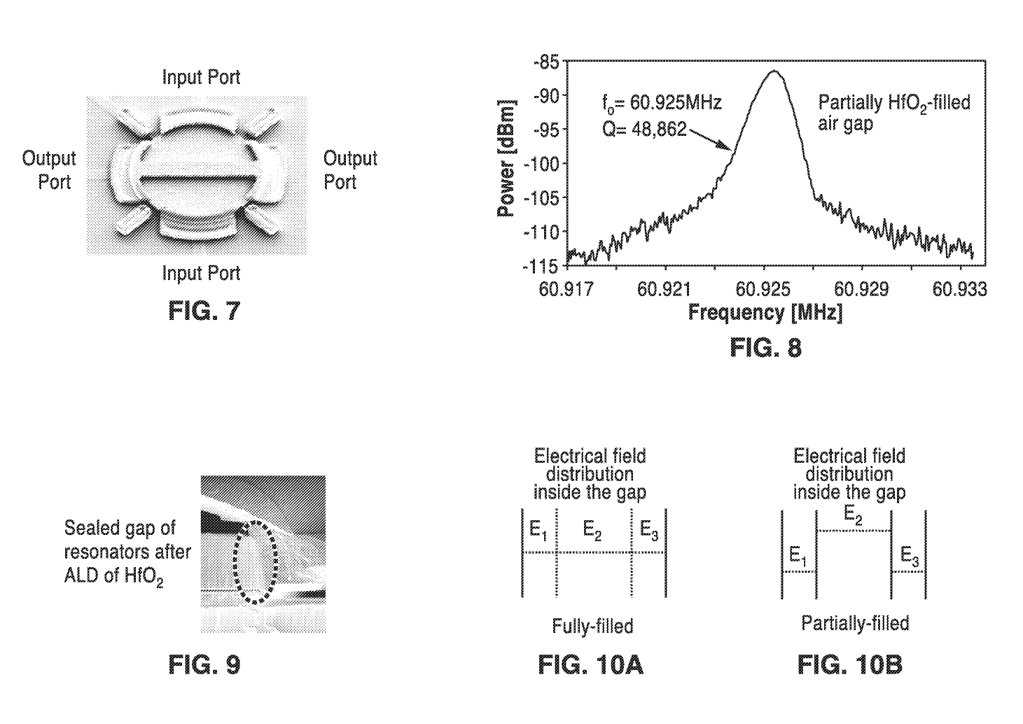

FIG. 7 illustrates another embodiment of wine-glass disk micromechanical resonator transducer (SEM image) having a partially filled HfO₂ gap according to the present invention, and shown having two input and two output ports.

FIG. 8 depicts the response of the resonator in FIG. 7, showing a resonant frequency of 60.925 MHz with a measured Q of 48,862.

FIG. 9 is an SEM image of a sealed gap of a resonator after ALD processing of HfO₂. It should be noted that the scaling of resonators for high-frequency also scales their capacitive overlaps toward increasing motional resistances, such as according to:

$${R}_{x} ∝ \frac{{d}^{4}}{{ɛ}_{r}^{2} {V}_{P}^{2}}$$

FIGS. 10A-10B depict electrical field distribution within a fully-filled gap (FIG. 10A) and a partially-filled gap (FIG. 10B).

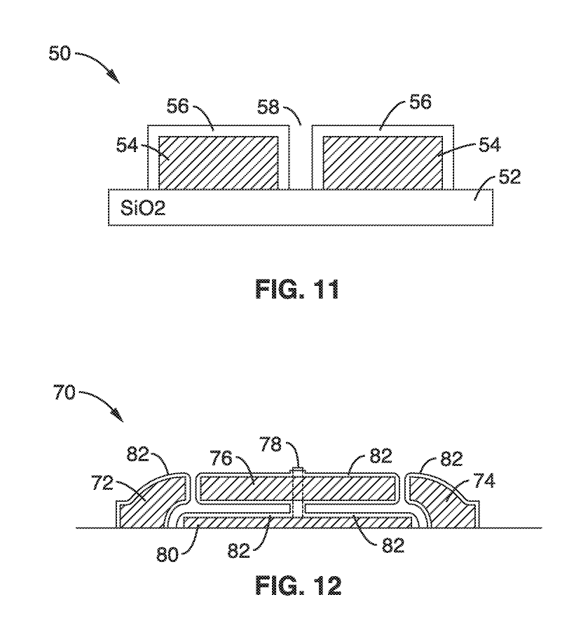

FIGS. 11-12 illustrate alternative strategies for creating tiny gaps within the resonator structures. In FIG. 11 an embodiment 50 is shown in which an oxide layer 56 is grown, for example by a thermal process, on the resonator surface, such as comprising poly Si 54. The figure shows a cross section of the resonator disk with stem portion 58 in the center of the disk. Clearly, FIG. 11 depicts an early portion of the processing. The substrate 52 is shown of SiO₂ although other materials may be similarly utilized, such as nitride or Si₃H₄. A highly conformal coating is provided which can be readily removed since grown over the poly Si. In FIG. 12 an embodiment 70 is shown with a gap being filled in response to an additive, oxidizing, process performed to make the gaps smaller. The figure shows input electrode 72, output electrode 74, disk 76, supporting stem 78 and base 80. A conformal oxide layer 82 is shown being grown to fill the gap within the structure. It will be appreciated that the effective oxide gap is between the surfaces. It should also be noted that the oxide provides a means of temperature compensation.

Although the description above contains many details, these should not be construed as limiting the scope of the invention but as merely providing illustrations of some of the presently preferred embodiments of this invention. Therefore, it will be appreciated that the scope of the present invention fully encompasses other embodiments which may become obvious to those skilled in the art, and that the scope of the present invention is accordingly to be limited by nothing other than the appended claims, in which reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 U.S.C. 112, sixth paragraph, unless the element is expressly recited using the phrase “means for.”

What is claimed is:

1. A micromechanical resonator device having a capacitive-transducer, comprising:
at least one input electrode;
at least one output electrode;
at least one resonator element retained proximal said input and output electrodes and adapted to provide sufficient unimpeded mechanical displacement for resonance;
wherein a gap of distance d₁, first gap distance, exists between said resonator element and said input electrodes and/or said output electrodes;
a dielectric material disposed on said resonator element, said electrodes, or a combination of said resonator element and said electrodes, to partially fill first gap distance d₁ between said resonator element and said electrodes resulting in a smaller second gap distance d₂;
wherein reduction of said gap by said partial fill with said dielectric lowers the motional resistance of the micromechanical resonator device leading to a lowering of the capacitively-transduced resonator impedance.

2. A micromechanical resonator device as recited in claim 1, wherein said motional resistance, Rₓ, across the resonator element is given by:
$${R}_{x} = \frac{{ω}_{0} {m}_{r}}{{{QV}_{P}^{2} ( \partial C / \partial x )}^{2}} \approx \frac{{ω}_{0} {m}_{r} {d}_{0}^{4}}{{{QV}_{P}^{2} ( {ɛ}_{0} {A}_{0} )}^{2}} ;$$
wherein ω₀ is the radian resonance frequency of the resonator element, mᵣ is equivalent dynamic mass of the resonator, Q is quality factor for the resonator, Vₚ is DC-bias voltage applied to the resonant element, ∂C/∂x is the change in electrode-to-resonator overlap capacitance per unit displacement, ε₀ is the permittivity in vacuum, A₀ is the electrode-to-resonator overlap area; and d₀ is the electrode-to-resonator gap spacing.

3. A micromechanical resonator device as recited in claim 1, wherein if said partial filling of said d₁ gap is performed so that said second gap distance d₂ is sufficiently greater than zero, then said disk resonator is allowed unimpeded displacement.

4. A micromechanical resonator device as recited in claim 1, wherein said dielectric material has a sufficient dielectric constant ε_{fill} as given by,
$${ɛ}_{fill} \geq 20 {ɛ}_{0} \frac{{d}_{fill}}{{d}_{air}} \to C ( x ) \approx {C}_{air} ( x ) ;$$
wherein ε₀ is the permittivity in a vacuum, d_{fill}, is the amount of filling on each side of the gap and dₐᵢᵣ is the resultant gap, Cₐᵢᵣ is the capacitance across the gap, C_{fill} is the capacitance across each dielectric-filled region, and x is displacement.

5. A micromechanical resonator device as recited in claim 1, wherein said micromechanical resonator device can be fabricated to have a center frequency within the MHz through GHz frequency ranges.

6. A micromechanical resonator device as recited in claim 1, wherein said partial filling of said gap overcomes fabrication limitations which restrict achieving a smaller gap between the resonator and electrodes.

7. A micromechanical resonator device as recited in claim 1, wherein said micromechanical resonator device is configured for use within ultra-stable oscillators, RF filtering devices, radar systems, and communication systems.

8. A micromechanical resonator device as recited in claim 1, wherein said capacitively-transduced resonator impedance can be lowered to any desired impedance down to a value of approximately 5Ω or less.

9. A micromechanical resonator device as recited in claim 1, wherein the size and geometry of said resonator element is configured based on the desired frequency response and application of said micromechanical resonator device.

10. A micromechanical resonator device as recited in claim 1, wherein high-Q levels of greater than 10,000 can be maintained when partial-filling said gap.

11. A micromechanical resonator device as recited in claim 1:
wherein said micromechanical resonator device is configured for receiving a bias on the resonant element and a signal source applied between said input and output electrodes; and
wherein the current output through said micromechanical resonator device is highly frequency dependent in response to micromechanical resonance.

12. A micromechanical resonator device as recited in claim 1, wherein the reduction of motional resistance of the resonator in response to said partial filling of the gap is given by (d₁/d₂)⁴.

13. A micromechanical resonator device as recited in claim 1, wherein said partial filling of said gap is performed in response to an atomic layer deposition (ALD) process.

14. A micromechanical resonator device as recited in claim 1, wherein said partial filling of said gap is performed in response to an oxide growth process.

15. A micromechanical resonator device as recited in claim 1, wherein said micromechanical resonator device comprises a laterally-driven wine-glass disk resonator.

16. A micromechanical resonator device as recited in claim 15, wherein said resonator element comprises a resonator disk on the order of 20 μm in diameter.

17. A micromechanical resonator device having a capacitive-transducer, comprising:
a substrate;
at least one input electrode attached to said substrate;
at least one output electrode attached to said substrate;
at least one disk resonator element retained proximal said input and output electrodes and separated from said substrate to provide sufficiently unimpeded mechanical displacement;
wherein a gap of distance d₁ exists between said disk resonator element and said input electrodes and/or said output electrodes;
a dielectric material disposed on said disk resonator element, said electrodes, or a combination of said resonator element and said electrodes, to partially fill the gap distance between said disk resonator element and said electrodes to reduce first gap distance d₁ to a second gap distance d₂;
wherein reduction of said gap by said dielectric lowers the motional resistance of the micromechanical resonator device and results in lowered capacitively-transduced resonator impedance.

18. A micromechanical resonator device as recited in claim 17, wherein said motional resistance, Rₓ, across the resonator element is given by:
$${R}_{x} = \frac{{ω}_{0} {m}_{r}}{{{QV}_{P}^{2} ( \partial C / \partial x )}^{2}} \approx \frac{{ω}_{0} {m}_{r} {d}_{0}^{4}}{{{QV}_{P}^{2} ( {ɛ}_{0} {A}_{0} )}^{2}} ;$$
wherein ω₀ is the radian resonance frequency of the resonator element, mᵣ is equivalent dynamic mass of the resonator, Q is quality factor for the resonator, Vₚ is DC-bias voltage applied to the resonant element, ∂C/∂x is the change in electrode-to-resonator overlap capacitance per unit displacement, ε₀ is the permittivity in vacuum, A₀ is the electrode-to-resonator overlap area; and d₀ is the electrode-to-resonator gap spacing.

19. A micromechanical resonator device as recited in claim 17, wherein said dielectric material has a sufficient dielectric constant ε_{fill} as given by,
$${ɛ}_{fill} \geq 20 {ɛ}_{0} \frac{{d}_{fill}}{{d}_{air}} \to C ( x ) \approx {C}_{air} ( x ) ;$$
wherein ε₀ is the permittivity in a vacuum, d_{fill} is the amount of filling on each side of the gap and dₐᵢᵣ is the resultant gap, Cₐᵢᵣ is the capacitance across the gap, C_{fill} is the capacitance across each dielectric-filled region, and x is displacement.

20. A method of raising the efficacy of a capacitive-transducer within a micromechanical resonator device, comprising:
fabricating at least one movable resonator element proximal to at least one input electrode and at least one output electrode;
said resonator element configured with a gap between said resonator element and said input and/or output electrodes comprising a first gap distance d₁;
at least partially-filling said gap with a dielectric material, wherein said first gap distance d₁ is reduced to a second gap distance d₂; and
wherein reduction of said gap from said first gap distance d₁ to said second, smaller, gap distance d₂ raises the efficacy of the capacitive-transducer in its ability to move the structure in response to application of input signals while lowering capacitively-transduced resonator impedance.
